(19) United States
(12) Patent Application Publication
(10) Pub. No.: US 2025/0112562 A1
(43) Pub. Date: Apr. 3, 2025

(54) SEMICONDUCTOR DEVICE

(71) Applicant: HITACHI ASTEMO, LTD., Ibaraki (JP)

(72) Inventors: Junpei KUSUKAWA, Tokyo (JP); Takeshi TOKUYAMA, Tokyo (JP); Takahiro ARAKI, Tokyo (JP); Ti CHEN, Tokyo (JP)

(21) Appl. No.: 18/729,865

(22) PCT Filed: Dec. 27, 2022
(86) PCT No.: PCT/JP2022/048392

§ 371 Date: Jul. 17, 2024

(30) Foreign Application Priority Data
Feb. 2, 2022 (JP) 2022-015058

(51) Int. Cl. H02M 7/00; H01L 23/00; H01L 23/31; H01L 23/367; H05K 1/02; H05K 1/18; H05K 3/46; H05K 7/20

(52) U.S. Cl. CPC H02M 7/003; H01L 23/3121; H01L 23/3672; H05K 1/0298; H05K 1/183; H05K 3/4697; H05K 7/20927; H01L 24/48; H01L 2224/48245; H01L 2924/13055

(57) ABSTRACT

A power conversion device is provided with: a semiconductor device, two heat spreaders, and an external terminal; a circuit board having a first insulating layer; and a cooler. The circuit board has: a recessed section for the semiconductor device; a first conductor layer that forms a bottom surface of the recessed section; and a second conductor layer that is disposed in a layer different from the first conductor layer and which is exposed in the recessed section. One of the heat spreaders is in contact with the bottom surface of the recessed section and is bonded to the first conductor layer with a first metal bonding material. The external terminal is bonded to the second conductor layer with a second metal bonding material. The cooler is in press contact with the other of the heat spreaders with a second insulating layer different from the first insulating layer interposed therebetween.

### TECHNICAL FIELD

The present invention relates to a semiconductor device.

### BACKGROUND ART

Power converters using power semiconductor elements are widely used in fields such as consumer use, automobile use, railway use, industrial use, and infrastructure use. For example, a power semiconductor element for an automobile is applied to an electric vehicle (EV) driven by a motor, a hybrid car (HEV) in which motor drive and engine drive are combined, and the like. In these EV and HEV, in the DC voltage of a battery, a pseudo AC voltage is generated by switching the power semiconductor element, and the motor is driven with high efficiency. In a power converter including this power semiconductor element, it is required to mount a circuit component having a high voltage on a printed board so as not to impair reliability.

PTL 1 discloses a configuration of an electric device in which a recess is formed in a thickness direction of a printed board, a circuit component having a high voltage is disposed in the recess, and the recess is filled with an insulating material to secure insulation of the high-voltage component and suppress an increase in the number of components and the number of manufacturing steps in application of the insulating material.

### CITATION LIST

### Patent Literature

PTL 1: JP 2020-77744 A

### SUMMARY OF INVENTION

### Technical Problem

In a case where an amount of heat generated by a power module including the electronic component increases, it is necessary to dissipate heat to a cooler. However, in a conventional configuration, depending on the installation situation of the power module included in the board, heat dissipation may decrease, and the reliability of the entire device may decrease. In view of this, an object of the present invention is to provide a power converter in which heat dissipation, vibration resistance, connection reliability, and insulation reliability are improved.

### Solution to Problem

A power converter according to the present invention includes: a semiconductor device which includes a semiconductor element, two heat spreaders each of which is bonded to one surface side of both surfaces of the semiconductor element, and an external terminal, and is sealed with an insulating resin such that another surface of each of the two heat spreaders and a part of the external terminal are exposed; a circuit board on which the semiconductor device is mounted and which has a first insulating layer; and a cooler for cooling the semiconductor device. The circuit board has a recess in which the semiconductor device is installed, a first conductor layer which forms a bottom surface of the recess, and a second conductor layer which is arranged in a layer different from the first conductor layer and at least partially exposed in the recess, one of the two heat spreaders is in contact with the bottom surface of the recess on the another surface and is bonded to the first conductor layer via a first metal bonding material, the external terminal is bonded to the second conductor layer via a second metal bonding material, and another of the two heat spreaders is in pressure contact with the cooler on the another surface via a second insulating layer different from the first insulating layer.

### Advantageous Effects of Invention

According to the present invention, it is possible to provide a power converter in which heat dissipation performance, vibration resistance, connection reliability, and insulation reliability are improved.

### BRIEF DESCRIPTION OF DRAWINGS

FIG. 1 is a cross-sectional view of a conventional power converter.

FIG. 2A is a diagram illustrating a cross-sectional structure of an embodiment of a power converter of the present invention.

FIG. 2B is a view illustrating a cross-sectional structure of the semiconductor device.

FIG. 3 is a diagram illustrating a cross-sectional structure of an embodiment of the power converter of the present invention.

FIG. 4 is a diagram illustrating a cross-sectional structure of an embodiment of the power converter of the present invention.

FIG. 5 is a cross-sectional view of a circuit board illustrating a step of forming a first conductor layer.

FIG. 6 is a cross-sectional view of a circuit board illustrating a step of forming a first conductor layer according to an embodiment of the power converter of the present invention.

Hereinafter, embodiments of the present invention will be described with reference to the drawings. The following description and drawings are examples for describing the present invention, and are omitted and simplified as appropriate for the sake of clarity of description. The present invention can be carried out in various other forms. Unless otherwise specified, each component may be singular or plural.

The position, size, shape, range, and the like of each component illustrated in the drawings may not represent the actual position, size, shape, range, and the like in order to facilitate understanding of the invention. Therefore, the present invention is not necessarily limited to the position, size, shape, range, and the like disclosed in the drawings.

### (Conventional Configuration)

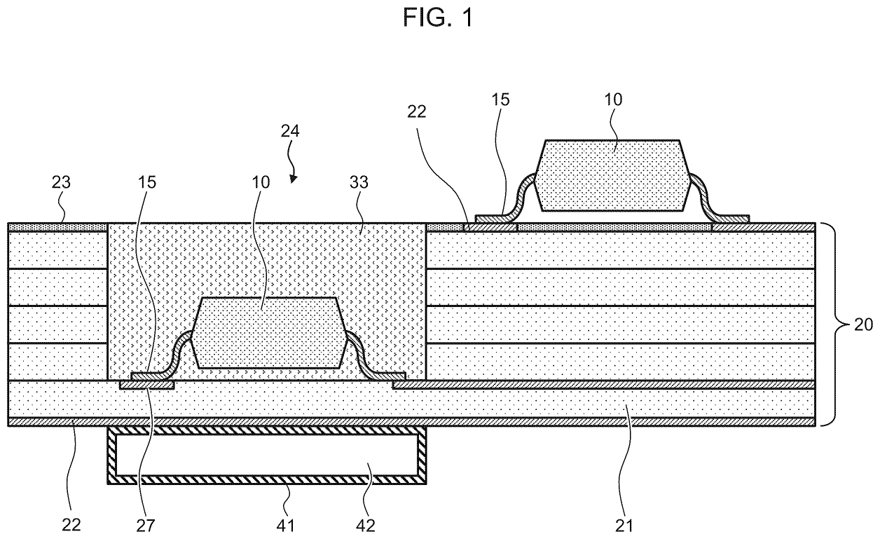

### (FIG. 1)

An electronic component 10 included in the power converter has an external terminal 15 for connection with a circuit conductor 22 of a circuit board 20. In the circuit board 20, a solder resist 23 which is an insulating film is provided on the entire surface in order to protect a circuit pattern including the circuit conductor 22.

When the electronic component 10 is, for example, a precision instrument such as a power module (semiconductor device) including a power semiconductor element (hereinafter, a semiconductor element), it is necessary to protect the circuit board 20 with an insulating resin. Therefore, a recess 24 is formed in the circuit board 20, the electronic component 10 is disposed inside the recess 24, and an insulating resin filler 33 is filled between the recess 24 and the electronic component 10. In addition, a cooler 41 having a water passage 42 is disposed on an opposite side of the recess 24 with a bottom surface (an insulating layer 21 of the circuit board 20) of the recess 24 interposed therebetween. In this way, a power converter that achieves both stability and heat dissipation of the electronic component 10 is realized, and reliability is improved.

However, for example, in a case where a solder paste used for bonding is not constant when the power module is disposed in the recess 24, there is a possibility that the power module is installed to be shifted or inclined with respect to the circuit board 20, so that reliability cannot be maintained with respect to electrical connection and stability.

### (Power Converter According to an Embodiment of the Present Invention)

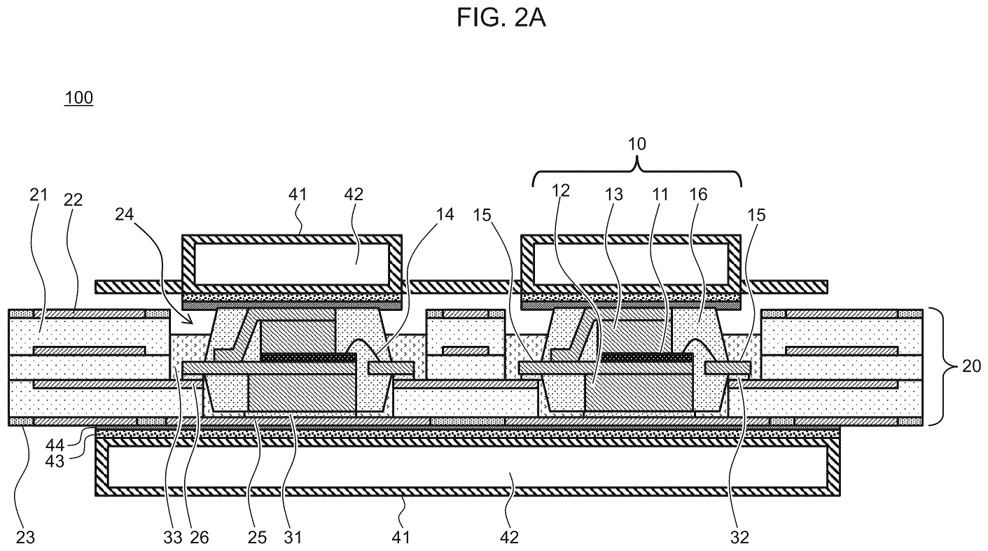

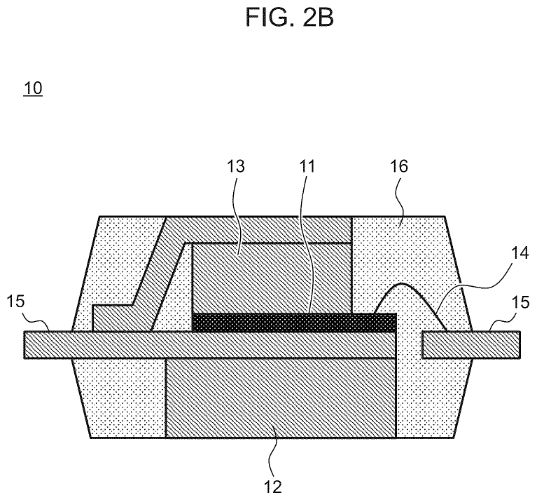

### (FIGS. 2A and 2B)

A basic structure of the power converter will be described. A power converter 100 includes a power module (semiconductor device 10) including a semiconductor element 11 such as an insulated gate bipolar transistor (IGBT), the printed circuit board 20, the cooler 41, a bus bar, a capacitor, and the like (not illustrated). Note that FIG. 2A illustrates an example in which the power converter 100 includes two semiconductor devices 10 and these are mounted on the circuit board 20, but the number of semiconductor devices 10 is not limited to two and may be any number. In the power converter 100, the semiconductor device 10 generates heat by switching of a large current in the semiconductor element 11, and the circuit board 20, the bus bar, the capacitor, and the like also generate heat with a loss due to an electrical resistance component of each material, in proportion to the product of the squares of currents flowing through the circuit board, the bus bar, the capacitor, and the like. The cooler 41 cools these heat generating components.

The power converter 100 having such a structure is mounted on an HEV or an EV. In contrast to the HEV that travels by assisting the driving force of a motor with the driving force of an engine, the EV travels only by the driving force of the motor, which is a purely electric force, so that the power converter 100 is required to be able to handle larger electric power. In a case where the current is increased, a loss increases in proportion to the square of the current, and the amount of generated heat increases, and thus, in order to reduce the heat generation, it is necessary to increase the amount of the conductor used for the power converter 100 and reduce a conductor resistance. As a result, the volume and weight of the power converter 100 increase, which causes an increase in size. In addition, since an increase in cruising distance is a problem in the EV, it is necessary to increase the capacity of the battery to be mounted, and accordingly, downsizing and weight reduction of the power converter 100 are required.

The semiconductor device 10 will be described. Heat spreaders 12 and 13 are bonded to both surfaces of the semiconductor element 11 via solder (not illustrated), and (the control terminal of) the semiconductor element 11 and the external terminal 15 are electrically bonded by using a wire 14. The semiconductor device 10 is sealed by transfer molding using the insulating resin 16 in a state where the surfaces of the heat spreaders 12 and 13 opposite to the surfaces bonded to the semiconductor element 11 are exposed and a part of the external terminal 15 is exposed.

The semiconductor device 10 is electrically connected by bonding the heat spreaders 12 and 13 to both surfaces of the semiconductor element 11, and includes the external terminal 15 for electrically connecting the semiconductor element 11 to the circuit board 20. In addition, the heat spreader 12 is connected to the bottom surface of the recess 24 provided in the circuit board 20 on the other surface not bonded to the semiconductor element 11, and the heat spreader 13 is connected to the cooler 41 on the other surface not bonded to the semiconductor element 11. Note that the semiconductor element 11 is, for example, an IGBT, and the heat spreader 12 connected to the collector electrode side is bonded to the bottom surface of the recess 24.

In the circuit board 20 on which the semiconductor device 10 is disposed, the first metal bonding material 31 is disposed on a first conductor layer 25 provided on the bottom surface of the recess 24. The first metal bonding material 31 is, for example, a solder sheet. In addition, a second metal bonding material 32 is applied and disposed on a second conductor layer 26 which is a board wiring layer one step higher from the first conductor layer 25 toward the upper side of the paper and is partially exposed at a step provided in the recess 24. The second metal bonding material is, for example, a solder paste. Accordingly, the external terminal 15 of the semiconductor device 10 can be bonded to the second conductor layer 26 of the circuit board 20 at a short distance without being bent, so that main circuit inductance can be reduced.

In addition, when the outer shape of the first conductor layer 25 is made larger than the outer shape of the heat spreader 12 of the semiconductor device 100 bonded via the first metal bonding material 31, heat from the semiconductor element 11 can be more efficiently spread by the first conductor layer 25, and heat dissipation performance can be improved.

Note that although the first metal bonding material 31 and the second metal bonding material 32 are applied and disposed by using the same solder material, different materials may be used as long as there is no problem in electrical connection and stability of the semiconductor device 100.

The semiconductor device 10 is mounted in the recess 24 such that the external terminal 15 is connected to the second conductor layer 26. By melting and solidifying each of the first metal bonding material 31 and the second metal bonding material 32 by a reflow device (not illustrated), the first conductor layer 25 is bonded to the heat spreader 12, and the second conductor layer 26 is bonded to the external terminal 15. Accordingly, the semiconductor device 10 is fixed to the recess 24. A gap between the semiconductor device 10 fixed by the reflow device and the recess 24 is filled with the resin filler 33 and cured at a predetermined temperature. In this way, high insulation reliability can be obtained even in a case where a high voltage is applied.

The cooler 41 is brought into pressure contact with the semiconductor device 10 from both upper and lower directions, and an insulating layer 43, which is a highly thermally conductive insulating sheet made of a mixture of an inorganic filler and an epoxy resin and having a high thermal conductivity, is attached to the pressure contact surface. Further, an electrically insulating heat dissipation material 44 is applied onto the insulating layer 43. Note that for the insulating layer 43, a ceramic plate such as aluminum nitride or silicon nitride may be used instead of the highly thermally conductive resin sheet.

The cooler 41 is brought into press contact with the semiconductor device 10 installed in the recess 24 of the circuit board 20 from the opening side of the recess 24 via the insulating layer 43 and the electrically insulating heat dissipation material 44. On the other hand, the cooler 41 is also brought into pressure contact with the outer side surface of the bottom surface of the recess 24, and the heat dissipation of the semiconductor device 10 is improved by the double-sided cooling of the cooler 41.

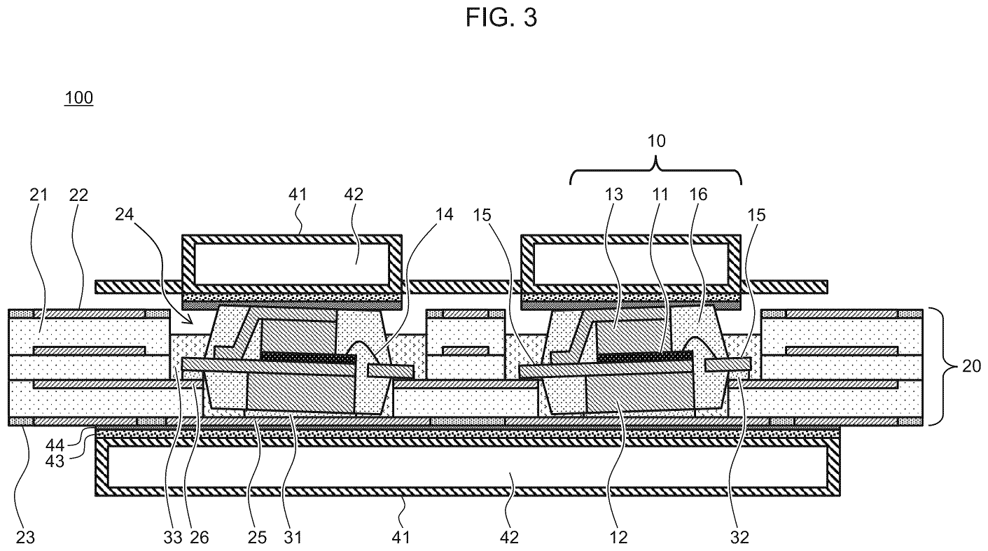

With such a configuration, the heat generated in the semiconductor element 11 is transmitted to the first conductor layer 25 forming the bottom surface of the recess 24 of the circuit board 20 via the heat spreaders 12 and 13 bonded to the semiconductor element 11 and via the insulating resin 16 or the metal bonding materials 31 and 32 having lower thermal resistance than that of the insulating layer 21 of the circuit board 20. The heat that has reached the first conductor layer 25 is dissipated from the outer side surface of the surface of the circuit board 20 on which the recess 24 is formed, to the cooler 41 that is in pressure contact via the insulating layer 43 different from the insulating layer 21 of the circuit board 20, so that the heat dissipation performance of the semiconductor device 10 is improved. In addition, as will be described later with reference to FIG. 3, in a case where the semiconductor device 10 is inclined at the time of installation, the metal bonding material 31 is provided to absorb the inclination and maintain the reliability of the device 10 without deteriorating the heat dissipation performance. In addition, unnecessary increase in size is prevented, which also contributes to downsizing of the device.

In addition, since the heat spreader 12 is bonded to the first conductor layer 25 via the first metal bonding material 31, as compared with a case where only the external terminal 15 of the semiconductor device 10 and the second conductor layer 26 of the circuit board 20 are metal-bonded, a bonding area between the semiconductor device 10 and the circuit board 20 can be increased, and vibration resistance and connection reliability are improved.

### (FIG. 3)

In the power converter 100, even in a case where the semiconductor device 10 is mounted to be inclined with respect to the circuit board 20, the first metal bonding material 31 absorbs the inclination of the semiconductor device 10, so that the reliability of the semiconductor device 10 can be maintained.

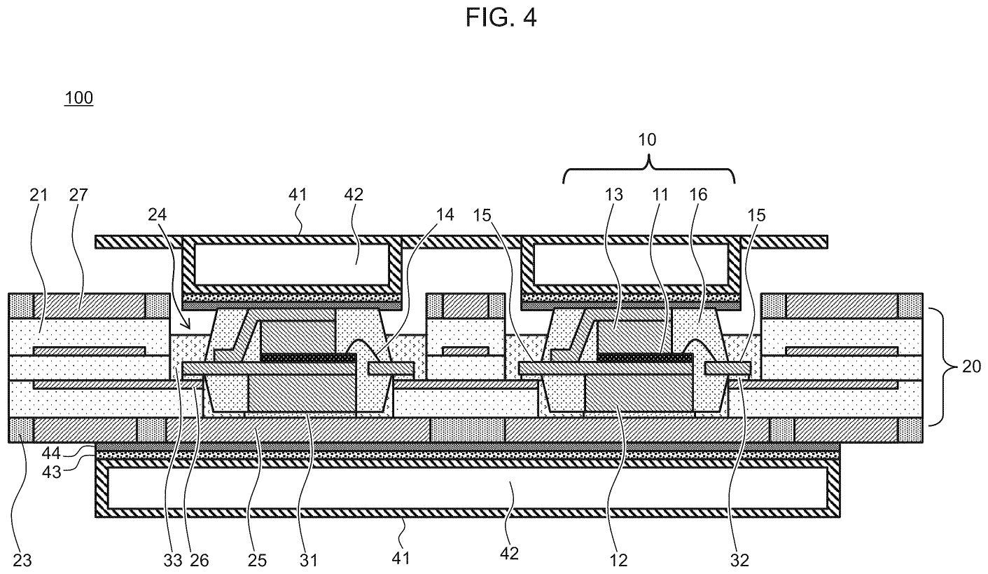

### (FIG. 4)

In the power converter 100, the circuit board 20 including the semiconductor device 10 is provided with the recess 24, and thus, the entire board may be warped to cause a defect. Therefore, the first conductor layer 25 included in the circuit board 20 is made thick copper, and accordingly, the conductor layer on the opposite side of the circuit board 20 is also made a thick copper circuit conductor 27. In this way, the warpage of the entire circuit board 20 and semiconductor device 10 can be reduced, and the heat dissipation can also be improved without impairing the reliability of the device. Note that in this configuration, both the first conductor layer 25 and the thick copper circuit conductor 27 have a thickness of 1 mm.

### (Method of Manufacturing Board)

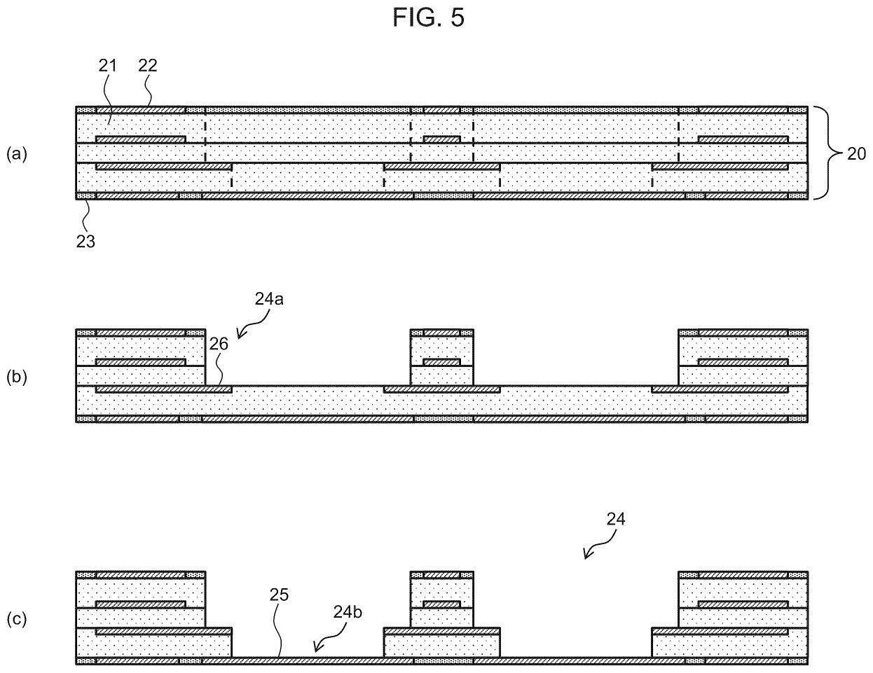

### (FIG. 5)

First, as illustrated in FIG. 5 (a), a multilayer printed board in which four conductor layers 22 are provided on the circuit board 20 is prepared. Note that since the current handled by the power converter is several hundred A (amperes), the conductor layer 22 of the circuit board 20 is made of copper foil 500 μm, which is thicker than the copper foil generally used in electronic instruments. In addition, a glass fiber-reinforced epoxy resin base material is used for the insulating layer 21 of the circuit board 20. Each conductor layer 22 of the circuit board 20 has the copper foil formed in advance by etching, so as to be a circuit of the power converter.

Next, in FIG. 5 (b), by counterboring at a location of the circuit board 20 where the semiconductor device is disposed, a recess 24a was formed up to a position where a third conductor layer surface (the second conductor layer 26 described above) from the top is visible.

In FIG. 5 (c), a partial exposed location of the second conductor layer 26 is left with respect to the recess 24a formed in FIG. 5 (b), and further a recess 24b is formed to a position where a fourth conductor layer surface (first conductor layer 25) from the top is visible, similarly by counterboring. Accordingly, the recess 24 is formed in the circuit board 20.

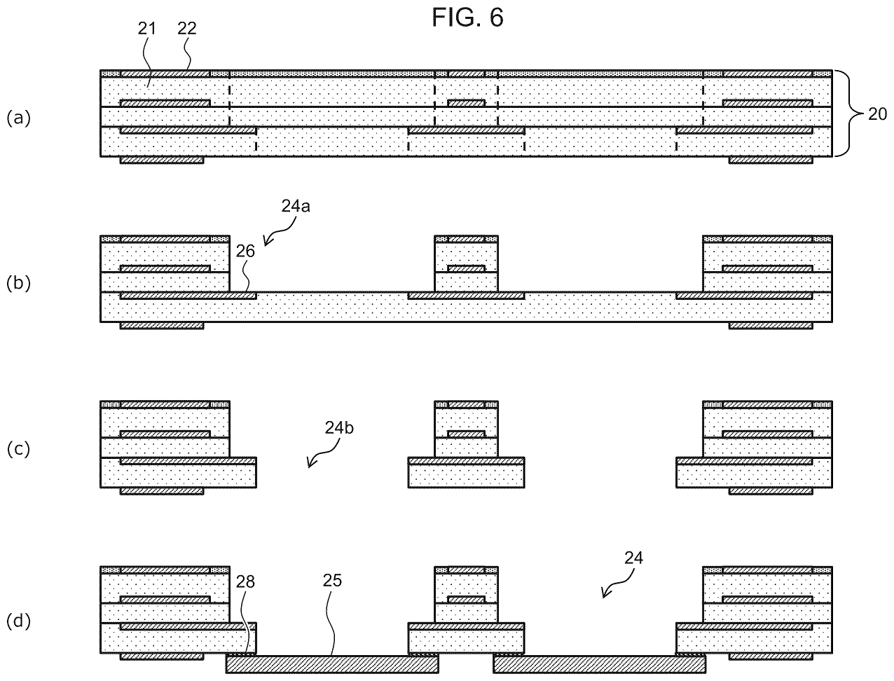

### (FIG. 6)

A method of manufacturing the circuit board 20 provided with the first conductor layer 25 that is thick copper described with reference to FIG. 4 will be described. The circuit board 20 is manufactured by a method different from the method described with reference to FIG. 5. First, as illustrated in FIG. 6 (a), a multilayer printed board having four conductor layers 22 is prepared as the circuit board 20. Note that the current to be handled, the material of the conductor layer, the material of the insulating layer, and the formation of the conductor layer of the circuit board 20 are similar to those in FIG. 5.

Next, in FIG. 6 (b), by counterboring at the location of the circuit board 20 where the semiconductor device 10 is disposed, the recess 24a is formed up to a position where the third conductor layer surface (second conductor layer 26) of from the top is visible. In FIG. 6 (c), a partial exposed location of the second conductor layer 26 is left, and the recess 24b is formed which is opened to allow the circuit board 20 to be penetrated. In FIG. 6 (d), a copper plate having a thickness of 1 mm different from that of the copper foil of the conductor layer 22 of the circuit board 20 is bonded to the bottom surface side of the recess 24b of the circuit board 20 by using an adhesive 28, so that the recess 24b penetrated in FIG. 6 (c) is formed with the first conductor layer 25 to complete the recess 24 of the circuit board 20. Note that from a viewpoint of achieving both heat dissipation of the semiconductor device 10 and inductance reduction due to bonding of the second conductor layer 26 and the external terminal 15 at a close position, the first conductor layer 25 is formed to partially overlap the second conductor layer 26 in the thickness direction of the circuit board 20.

In this way, the thickness of the first conductor layer 25 is not affected by restrictions on the manufacturing of the circuit board 20, so that a thicker conductor layer 25 can be formed according to a demand, and heat dissipation performance can be improved.

According to the embodiment of the present invention described above, the following operational effects are exhibited.

(1) The power converter 100 includes: the semiconductor device 10 which includes the semiconductor element 11, two heat spreaders 12 and 13 each of which is bonded to one surface side of both surfaces of the semiconductor element 11, and the external terminal 15, and is sealed with the insulating resin 16 such that another surfaces of each of the two heat spreaders 12 and 13 and a part of the external terminal 15 are exposed; the circuit board 20 on which the semiconductor device 10 is mounted and which has the first insulating layer 21; and a cooler for cooling the semiconductor device 10. The circuit board 20 includes the recess 24 in which the semiconductor device 10 is installed, the first conductor layer 25 forming a bottom surface of the recess 24, and the second conductor layer 26 which is arranged in a layer different from the first conductor layer 25 and at least partially exposed in the recess 24. One heat spreader 12 of the two heat spreaders 12 and 13 is in contact with the bottom surface of the recess 24 on the another surface and is bonded to the first conductor layer 25 via the first metal bonding material 31, the external terminal 15 is bonded to the second conductor layer 26 via the second metal bonding material 32, and another heat spreader 13 of the two heat spreaders 12 and 13 is in pressure contact with the cooler 41 on the another surface via the second insulating layer 43 different from the first insulating layer 21. With this configuration, it is possible to provide the power converter 100 in which heat dissipation performance, vibration resistance, connection reliability, and insulation reliability are improved.

(2) The first conductor layer 25 is formed to partially overlap the second conductor layer 26 in a thickness direction of the circuit board 20. With this configuration, it is possible to achieve both heat dissipation of the power converter 100 and inductance reduction.

(3) The first conductor layer 25 has an outer shape larger than an outer shape of the another surface of the heat spreader 12 exposed from the insulating resin 16. With this configuration, the heat dissipation performance of the power converter 100 can be improved.

(4) The insulating resin filler 33 is filled between the recess 24 and the semiconductor device 10. With this configuration, the power converter 100 can obtain high insulation reliability even in a case where a high voltage is applied.

(5) The first metal bonding material 31 and the second metal bonding material 32 have the same composition. With this configuration, the productivity of the power converter 100 can be improved.

(6) The semiconductor element 11 is an IGBT, and the heat spreader 12 on a collector electrode side of the IGBT is bonded to the bottom surface of the recess 24. With this configuration, it is possible to improve the heat dissipation of the power converter 100 using the IGBT.

(7) The circuit board 20 employs a manufacturing method including: preparing the circuit board 20 having a plurality of conductor layers 22; and forming an opening in the circuit board 20 by opening the circuit board 20 to a surface of a certain conductor layer 22 and performing counterboring to penetrate from an inner peripheral side of the surface of the certain conductor layer 22 to an opposite side of the circuit board 20, and forming the recess 24 in the circuit board 20 by bonding a copper plate to the opening. With this configuration, the present invention is not affected by restrictions on the manufacturing of the circuit board 20, so that a thicker conductor layer 25 can be formed according to a demand, and the heat dissipation performance can be improved.

Note that the present invention is not limited to the above embodiments, and various modifications and other configurations can be combined without departing from the gist of the present invention. In addition, the present invention is not limited to one including all the configurations described in the above embodiments, and includes one in which a part of the configuration is deleted.

### REFERENCE SIGNS LIST

10 electronic component (semiconductor device)
11 power semiconductor element
12 heat spreader (collector side of IGBT)
13 heat spreader (emitter side of IGBT)
14 wire
15 external terminal
16 insulating resin
20 circuit board
21 insulating layer of circuit board
22 circuit conductor of circuit board
23 solder resist
24 recess of circuit board
24a first recess
24b second recess
25 first conductor layer
26 second conductor layer
27 thick copper circuit conductor
28 adhesive
31 first metal bonding material
32 second metal bonding material
33 resin filler
41 cooler
42 water passage of cooler
43 insulating layer of cooler
44 electrically insulating heat dissipation material
100 power converter

1. A power converter comprising:
a semiconductor device which includes a semiconductor element, two heat spreaders each of which is bonded to one surface side of both surfaces of the semiconductor element, and an external terminal, and is sealed with an insulating resin such that another surface of each of the two heat spreaders and a part of the external terminal are exposed;
a circuit board on which the semiconductor device is mounted and which has a first insulating layer; and
a cooler for cooling the semiconductor device, wherein
the circuit board has a recess in which the semiconductor device is installed, a first conductor layer which forms a bottom surface of the recess, and a second conductor layer which is arranged in a layer different from the first conductor layer and at least partially exposed in the recess,
one of the two heat spreaders is in contact with the bottom surface of the recess on the other surface and is bonded to the first conductor layer via a first metal bonding material,
the external terminal is bonded to the second conductor layer via a second metal bonding material, and
another of the two heat spreaders is in pressure contact with the cooler on the other surface via a second insulating layer different from the first insulating layer.

2. The power converter according to claim 1, wherein
the first conductor layer is formed to partially overlap the second conductor layer in a thickness direction of the circuit board.

3. The power converter according to claim 1, wherein
the first conductor layer has an outer shape larger than an outer shape of the other surface of the heat spreader exposed from the insulating resin.

4. The power converter according to claim 1, wherein
an insulating resin filler is filled between the recess and the semiconductor device.

5. The power converter according to claim 1, wherein
the first metal bonding material and the second metal bonding material have a same composition.

6. The power converter according to claim 1, wherein
the semiconductor element is an IGBT, and the heat spreader on a collector electrode side of the IGBT is bonded to the bottom surface of the recess.

7. A method of manufacturing a circuit board comprising:
preparing the circuit board having a plurality of conductor layers; and
forming an opening in the circuit board by opening the circuit board to a certain conductor layer surface and performing counterboring to penetrate from an inner peripheral side of the certain conductor layer surface to an opposite side of the circuit board, and forming a recess in the circuit board by bonding a copper plate to the opening.
